(19) United States
(12) Patent Application Publication
(10) Pub. No.: US 2009/0230554 A1
(43) Pub. Date: Sep. 17, 2009

(54) WAFER-LEVEL REDISTRIBUTION PACKAGING WITH DIE-CONTAINING OPENINGS

(75) Inventors: Matthew V. Kaufmann, Morgan Hill, CA (US); Teck (Keith) Yang Tan, Singapore (SI)

Correspondence Address: FIALA & WEAVER, P.L.L.C.;C/O CPA GLOBAL, P.O. BOX 52050, MINNEAPOLIS, MN, 55402, US

(73) Assignee: Broadcom Corporation, Irvine, CA (US)

(21) Appl. No.: 12/402,038

(22) Filed: Mar. 11, 2009

Related U.S. Application Data
(60) Provisional application No. 61/036,196, filed on Mar. 13, 2008.

(51) Int. Cl. H01L 23/48; H01L 21/00

(52) U.S. Cl. 257/738; 438/113; 257/E21.599; 257/E21.575; 257/E23.021

(57) ABSTRACT

Methods, systems, and apparatuses for integrated circuit packages, and processes for forming the same, are provided. In one example, an integrated circuit (IC) package includes a thick film material that forms a opening, a die, an insulating material, a redistribution interconnect on the insulating material, and a ball interconnect. The die is positioned in the opening. The insulating material covers the die and a surface of the thick film material, and fills a space adjacent to the die in the opening. The redistribution interconnect is formed on the insulating material. The redistribution interconnect has a first portion coupled to a terminal of the die through the layer of the insulating material, and a second portion that extends away from the first portion over the insulating material filling the space adjacent to the die in the opening. The ball interconnect is coupled to the second portion of the redistribution interconnect.

This application claims the benefit of U.S. Provisional Application No. 61/036,196, filed on Mar. 13, 2008, which is incorporated by reference herein in its entirety.

### BACKGROUND OF THE INVENTION

1. Field of the Invention

The present invention relates to integrated circuit packaging technology, and more particularly to wafer-level ball grid array packages.

2. Background Art

Integrated circuit (IC) chips or dies are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

An advanced type of BGA package is a wafer-level BGA package. Wafer-level BGA packages have several names in industry, including wafer level chip scale packages (WLCSP), among others. In a wafer-level BGA package, the solder balls are mounted directly to the IC chip when the IC chip has not yet been singulated from its fabrication wafer. Wafer-level BGA packages can therefore be made very small, with high pin out, relative to other IC package types including traditional BGA packages.

A current move to tighter fabrication process technologies, such as 65 nm, with a continuing need to meet strict customer reliability requirements and ongoing cost pressures, is causing difficulties in implementing wafer-level BGA package technology. For example, due to the small size of the die used in wafer-level BGA packages, in some cases there is not enough space to accommodate all of the package pins at the pin pitch required for the end-use application

Thus, what is needed are improved wafer-level packaging fabrication techniques that can provide BGA packages at smaller package sizes, while enabling all the necessary package signals to be made available outside of the package at a pin pitch suitable for end-use applications.

### BRIEF SUMMARY OF THE INVENTION

Methods, systems, and apparatuses for wafer-level integrated circuit (IC) packages are described. One or more redistribution layers route signals from terminals of a die past an edge of the die over a space filled with an insulating material. Pins (e.g., ball interconnects) are coupled to the redistribution layers over the insulating material to be used to mount a package formed by the die and insulating material to a circuit board. Routing the redistribution layers over the insulating material adjacent to the die effectively increases an area of the die to allow for additional space for signal pins.

In one example, an integrated circuit (IC) package includes a substantially planar thick film material that forms a opening, an integrated circuit die, a layer of insulating material, a redistribution interconnect on the layer of insulating material, and a ball interconnect. The integrated circuit die is positioned in the opening. The integrated circuit die has a plurality of terminals on a first surface of the integrated circuit die. The layer of the insulating material covers the first surface of the die and a surface of the thick film material, and fills a space (when present) adjacent to the die in the opening. The redistribution interconnect is formed on the first layer of the insulating material. The redistribution interconnect has a first portion and a second portion. The first portion is coupled to a terminal of the die through the layer of the insulating material. The second portion extends away from the first portion over the insulating material that fills the space adjacent to the die in the opening. The ball interconnect is coupled to the second portion of the redistribution interconnect.

In an example fabrication process, a wafer is singulated into a plurality of integrated circuit dies that each include one or more integrated circuit regions. Each integrated circuit region includes a plurality of terminals. A non-active surface of each of the plurality of dies is attached to a first surface of a substrate in a corresponding opening.

A substantially planar layer of an insulating material is formed over the first surface of the substrate to cover the dies in the openings on the substrate. At least one redistribution interconnect is formed on the insulating material for each die of the plurality of dies to have a first portion coupled to a terminal of a respective die and a second portion that extends away from the first portion over a portion of the insulating material adjacent to the respective die. A ball interconnect is coupled to each second portion. The dies are singulated into a plurality of integrated circuit packages that each include one or more dies of the plurality of dies and the portion of the insulating material adjacent to the included die.

In an example aspect of the fabrication process, a substantially planar layer of a thick film material is formed on the first surface of the substrate. A plurality of openings is formed in the layer of the thick film material. The dies are attached to the substrate by attaching a non-active surface of each die to the first surface of the substrate in a corresponding opening of the plurality of openings in the thick film material. The substantially planar layer of the insulating material is formed over a surface of the thick film material and over the dies, to cover the dies in the openings. When singulated into the plurality of integrated circuit packages, each package may include a portion of the thick film material.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a flowchart for forming integrated circuit packages, according to an embodiment of the present invention.

FIG. 2 shows a top view of an example wafer.

FIG. 3 shows a cross-sectional view of the wafer of FIG. 2, showing example first and second integrated circuit regions.

FIG. 4 shows a cross-sectional view of a wafer after having been thinned, according to an example embodiment of the present invention.

FIG. 5 shows a cross-sectional view of an adhesive material applied to a thinned wafer, according to an example embodiment of the present invention.

FIG. 6 shows a cross-sectional view of integrated circuit regions having been singulated into separate dies, according to an example embodiment of the present invention.

FIG. 7 shows a cross-sectional view of a substrate, according to an example embodiment of the present invention.

FIG. 8 shows a top view of the substrate of FIG. 7, with the substrate having a wafer form, according to an example embodiment of the present invention.

FIG. 9 shows a cross-sectional view of the substrate of FIG. 7 with a film layer formed thereon, according to an example embodiment of the present invention.

FIGS. 10 and 11 show cross-sectional and top views, respectively, of the substrate and film layer of FIG. 9, with openings formed in the film layer, according to an example embodiment of the present invention.

FIGS. 12 and 13 show cross-sectional and top views, respectively, of the substrate and film layer of FIG. 10, with dies inserted in the openings, according to an example embodiment of the present invention.

FIG. 14 shows a cross-sectional view of a layer of an insulating material applied to a substrate to cover attached dies, according to an example embodiment of the present invention.

FIG. 15 shows a flowchart providing example steps for forming redistribution interconnects, according to an embodiment of the present invention.

FIG. 16 shows a cross-sectional view of a substrate and attached dies covered with an insulating material, according to an embodiment of the present invention.

FIG. 17 shows example routing interconnects formed on the insulating material of FIG. 16, according to an embodiment of the present invention.

FIG. 18 shows a cross-sectional view of a second layer of an insulating material formed over the first layer of insulating material and redistribution interconnects, according to an example embodiment of the present invention.

FIG. 19 shows a cross-sectional view of a plurality of vias formed through the second layer of insulating material to provide access to redistribution interconnects, according to an example embodiment of the present invention.

FIG. 20 shows a cross-sectional view of under bump metallization layers formed in contact with respective redistribution interconnects through vias, according to an example embodiment of the present invention.

FIG. 21 shows a cross-sectional view of ball interconnects formed on under bump metallization layers, according to an example embodiment of the present invention.

FIG. 22 shows a plan view of ball interconnects for multiple dies that are spaced according to an example embodiment of the present invention.

FIG. 23 shows a cross-sectional view of a substrate after having been thinned, according to an example embodiment of the present invention.

FIG. 24 shows a cross-sectional view of integrated circuit packages having been singulated from each other, according to an example embodiment of the present invention.

FIG. 25 shows an integrated circuit package mounted to a circuit board, according to an example embodiment of the present invention.

FIG. 26 shows a bottom view of a package having a plurality of ball interconnects spaced according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Embodiments

“Wafer-level packaging” is an integrated circuit packaging technology where all packaging-related interconnects are applied while the integrated circuit dies or chips are still in wafer form. After the packaging-related interconnects are applied, the wafer is then tested and singulated into individual devices and sent directly to customers for their use. Thus, individual packaging of discreet devices is not required. The size of the final package is essentially the size of the corresponding chip, resulting in a very small package solution. Wafer-level packaging is becoming increasingly popular as the demand for increased functionality in small form-factor devices increases. These applications include mobile devices such as cell phones, PDAs, and MP3 players, for example.

The small size of wafer-level packages and the increasing integration of functionality into IC dies are making it increasingly difficult to attach enough pins (e.g., solder balls) to the wafer-level packages so that all desired signals of the dies can be externally interfaced. The pins of a device/package are limited to the surface area of the die. The pins on the die must be sufficiently spaced to allow end-users to surface mount the packages directly to circuit boards. If enough pins cannot be provided on the die, the end products will be unable to take advantage of the low cost and small size of the wafer-level packages. Such products will then need to use conventional IC packaging, which leads to much larger package sizes and is more costly.

Embodiments of the present invention enable wafer-level packages to have more pins than can conventionally be fit on a die surface at a pin pitch that is reasonable for the end-use application. Embodiments use routing interconnects to enable pins to be located over a space adjacent to the die, effectively increasing an area of the die. Such embodiments are cost-effective, manufacturable, and enable small size packages to be fabricated having large numbers of pins. The example embodiments described herein are provided for illustrative purposes, and are not limiting. Although wafer-level ball grid array packages are mainly illustrated in the description below, the examples described herein may be adapted to a variety of types of wafer-level integrated circuit packages and may include applications with more than one integrated circuit die. Further structural and operational embodiments, including modifications/alterations, will become apparent to persons skilled in the relevant art(s) from the teachings herein.

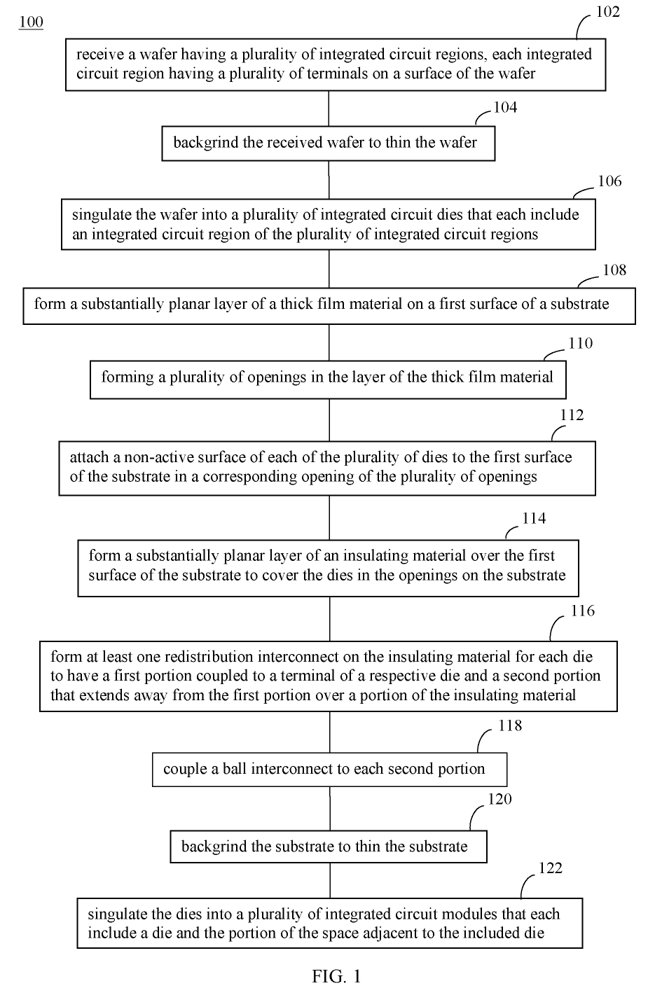

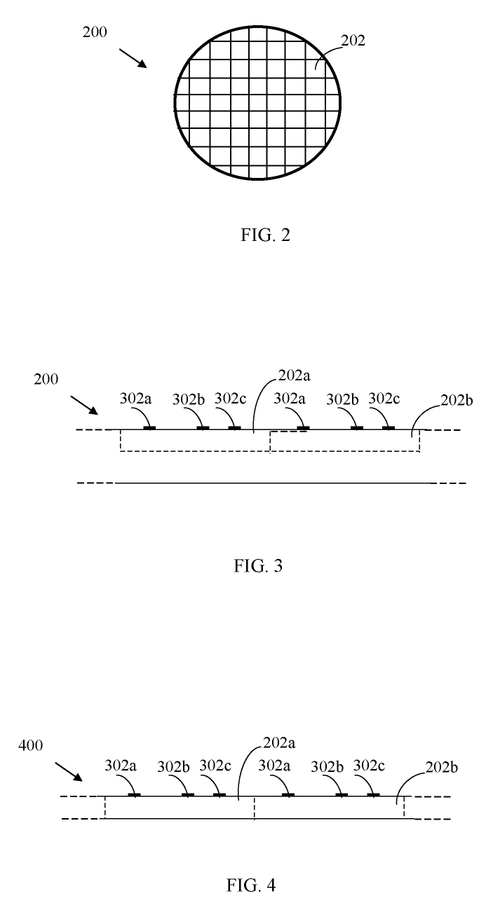

FIG. 1 shows a flowchart 100 for forming integrated circuit packages, according to an embodiment of the present invention. The formed integrated circuit packages have pins (e.g., ball interconnects) spaced more widely than an area of the corresponding die alone, and thus enable larger numbers of pins to be accommodated. The steps of flowchart 100 do not necessarily need to be performed in the order shown. All steps of flowchart 100 do not need to be performed in all embodiments. Flowchart 100 is described below with reference to FIGS. 2-24, for illustrative purposes. Other structural and operational embodiments will be apparent to persons skilled in the relevant art(s) based on the discussion provided herein.

Flowchart 100 begins with step 102. In step 102, a wafer is received having a plurality of integrated circuit regions, each integrated circuit region having a plurality of terminals on a surface of the wafer. For example, FIG. 2 shows a plan view of a wafer 200. Wafer 200 may be silicon, gallium arsenide, or other wafer type. As shown in FIG. 2, wafer 200 has a surface defined by a plurality of integrated circuit regions 202 (shown as small rectangles in FIG. 2). Each integrated circuit region 202 is configured to be packaged separately into a separate wafer-level integrated circuit package, such as a wafer-level ball grid array package. Any number of integrated circuit regions 202 may be included in wafer 200, including 10s, 100s, 1000s, and even larger numbers.

FIG. 3 shows a cross-sectional view of wafer 200, showing example first and second integrated circuit regions 202a and 202b. As shown in FIG. 3, integrated circuit regions 202a and 202b each include a plurality of terminals 302 (e.g., terminals 302a-302c). Terminals 302 are access points for electrical signals (e.g., input-output signals, power signals, ground signals, test signals, etc.) of integrated circuit regions 202. Any number of terminals 302 may be present on the surface of wafer 200 for each integrated circuit region 202, including 10s, 100s, and even larger numbers of terminals 302.

In step 104, the received wafer is thinned by backgrinding. Step 104 is optional. For instance, a backgrinding process may be performed on wafer 200 to reduce a thickness of wafer 200 to a desired amount, if desired and/or necessary. However, thinning of wafer 200 does not necessarily need to be performed in all embodiments. Wafer 200 may be thinned in any manner, as would be known to persons skilled in the relevant art(s). For instance, FIG. 4 shows a cross-sectional view of wafer 200 after having been thinned according to step 104, resulting in a thinned wafer 400. According to step 104, wafer 200 is made as thin as possible to aid in minimizing a thickness of resulting packages that will include integrated circuit regions 202.

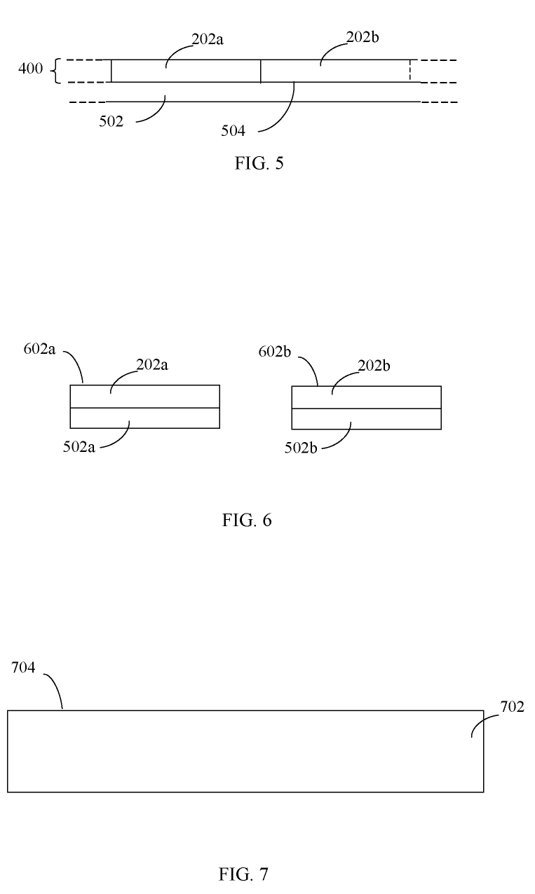

In an embodiment, flowchart 100 may optionally include the step of applying an adhesive material to a non-active surface of the wafer. For example, FIG. 5 shows a cross-sectional view of thinned wafer 400, with an adhesive material 502 applied to a non-active surface 504 of thinned wafer 400. Any suitable type of adhesive material may be used for adhesive material 502, including an epoxy, a conventional die-attach material, adhesive film, etc. This step is not necessarily performed in all embodiments, as further described below.

In step 106, the wafer is singulated into a plurality of integrated circuit dies that each include an integrated circuit region of the plurality of integrated circuit regions. Wafer 200 may be singulated/diced in any appropriate manner to physically separate the integrated circuit regions from each other, as would be known to persons skilled in the relevant art(s). For example wafer 200 may be singulated by a saw, router, laser, etc., in a conventional or other fashion. FIG. 6 shows a cross-sectional view of integrated circuit regions 202a and 202b having been singulated from each other (also including adhesive material 502a and 502b, respectively) into dies 602a and 602b, respectively. Singulation of wafer 200 may result in 10s, 100s, 1000s, or even larger numbers of dies 602, depending on a number of integrated circuit regions 202 of wafer 200.

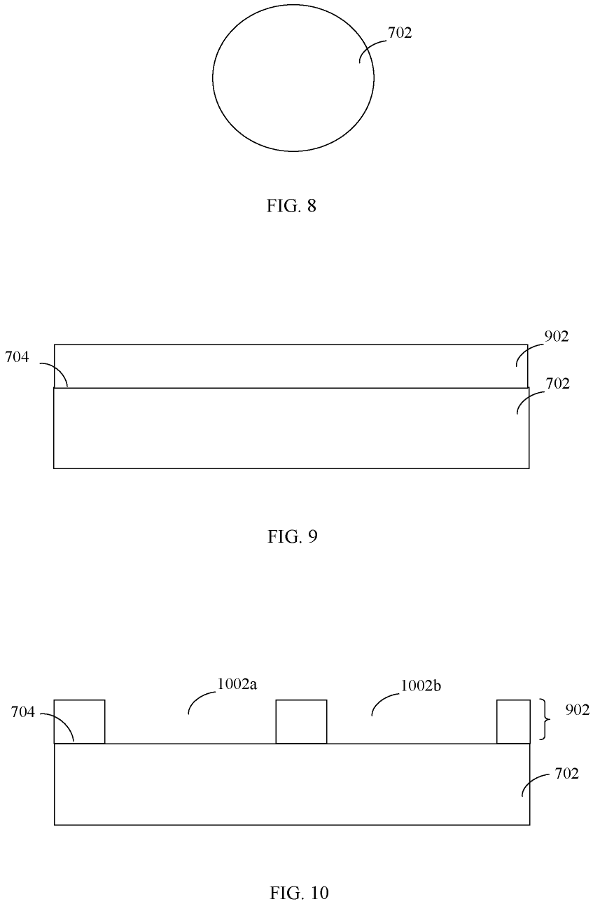

In step 108, a substantially planar layer of a thick film material is formed on a first surface of a substrate. FIG. 7 shows a cross-sectional view of a substrate 702 that may be processed in step 108, according to an example embodiment of the present invention. Substrate 702 can be any type of substrate material, including a dielectric material, a ceramic, a polymer, a semiconductor material, etc. For example, in an embodiment, substrate 702 is a wafer of a same material as wafer 200. For instance, wafer 200 and substrate 702 may both be silicon wafers. FIG. 8 shows a top view of substrate 702, where substrate 702 is a wafer, according to an example embodiment of the present invention. By having wafer 200 (and thus dies 602) and substrate 702 be the same material, dies 602 and substrate 702 will react similarly during subsequent processing and operation, and thus will be more likely to adhere to each other more securely (when attached to each other in a subsequent processing step, described below). For example, during temperature changes, dies 602 and substrate 702 will react similarly, such as by expanding or contracting uniformly, and thus will be less likely to detach from each other and less likely deviate from their placed positions to cause registration issues with subsequent lithography steps. Substrate 702 may be considered a “dummy” substrate, because substrate 702 may optionally be partially or entirely removed from dies 602 in a subsequent processing step, as described further below.

FIG. 9 shows a layer of a thick film material 902 formed on a first surface 704 of substrate 702. Thick film material 902 may be applied in any manner, conventional or otherwise, as would be known to persons skilled in the relevant art(s). For example, thick film material 902 may be applied according to a spin on or dry film process, and subsequently cured/dried, similar to a corresponding wafer-level process. Thick film material 902 may have a thickness less than, equal to, or greater than a thickness of dies 602 (and adhesive material 502). For example, thick film material 902 may have a thickness in the range of 50-200 μm. The thickness of thick film material 902 can be controlled by modifying parameters of the process used to form thick film material 902, and/or by forming multiple layers of thick film material 902 on first surface 702 (e.g., to stack layers of thick film material 902). Thick film material 902 may be formed or processed (e.g., polished) such that a substantially planar surface for thick film material 902 is formed on substrate 702. Thick film material 902 may be an electrically insulating material, such as a polymer, a dielectric material such as a photo-imagable dielectric, a standard spin-on dielectric material, and/or other suitable thick film material. For example, thick film material 902 may be SU-8 2000 or SU-8 3000, which are epoxy based photoresist materials supplied by MicroChem Corp. of Newton, Mass.

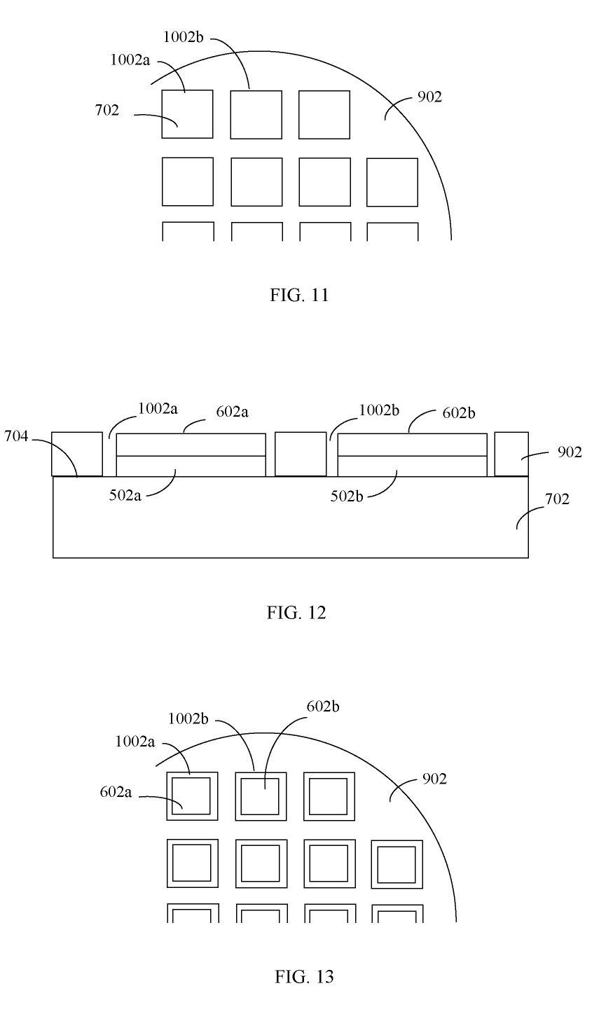

In step 110, a plurality of openings is formed in the layer of the thick film material. For example, FIG. 10 shows a cross-sectional of substrate 702 and thick film material 902, with a plurality of openings 1002 formed in thick film material 902, according to an example embodiment of the present invention. FIG. 11 shows a top view of a portion of substrate 702, with openings 1002 formed in thick film material 902 (in an embodiment where substrate 702 is a circular wafer). Openings 1002 may be formed/patterned in thick film material 902 in any arrangement, including in an array of rows and columns of openings 1002, as shown in FIG. 11. Openings 1002 may have a depth of an entire thickness of thick film material 902 (as shown in FIG. 10), or may have a depth that is less than an entire thickness of thick film material 902. Openings 1002 may have any shape, including being round, rectangular (as shown in FIG. 11), other polygon, or irregular. Openings 1002 may be formed in thick film material 902 in any suitable manner, including by etching (e.g., by laser etching, by a photolithographic process, by chemical etching, by mechanical etching, etc.), by drilling, or by other suitable process.

In step 112, a non-active surface of each of the plurality of dies is attached to the first surface of the substrate in a corresponding opening of the plurality of openings. For example, FIG. 12 shows a cross-sectional view of dies 602a and 602b attached to first surface 704 of substrate 702 in respective openings 1002a and 1002b. FIG. 13 shows a top view of the portion of substrate 702 shown in FIG. 11, with dies 602 positioned in openings 1002. As shown in FIG. 12, the non-active surface (i.e., surface 504 shown in FIG. 5) of each of dies 602a and 602b is attached to first surface 704 of substrate 702 by adhesive material 502a and 502b. For example, dies 602a and 602b may be positioned on substrate 702 in openings 1002a and 1002b, respectively, in any manner, including through the use of a pick-and-place apparatus, a self-aligning process, or other technique. After positioning of dies 602a and 602b, adhesive material 502a and 502b may be cured to cause dies 602a and 602b to become attached to substrate 702. Note that in embodiments, adhesive material 502 may be applied to first surface 704 of substrate 702 alternatively to, or in addition to applying adhesive material 502 on wafer 200/dies 602, as described above.

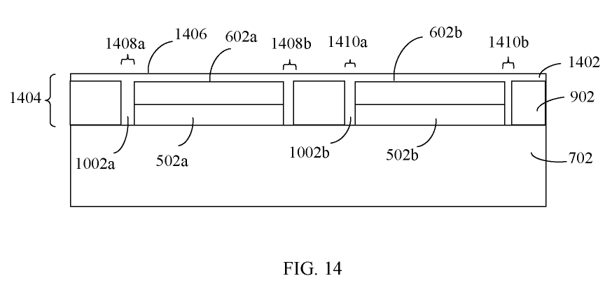

In step 114, a substantially planar layer of an insulating material is formed over the first surface of the substrate to cover the dies in the openings on the substrate. For instance, FIG. 14 shows a cross-sectional view of a layer 1404 of an insulating material 1402 applied to substrate 702 to cover dies 602a and 602b and thick film material 902. Insulating material 1402 may be applied in any manner, conventional or otherwise, as would be known to persons skilled in the relevant art(s). For example, insulating material 1402 may be applied according to a spin on or dry film process, and subsequently cured/dried, similar to a corresponding wafer-level process. Insulating material 1402 is applied such that layer 1404 has a thickness greater than a thickness of dies 602 (and adhesive material 502). Layer 1404 may be formed or processed (e.g., polished) such that a first surface 1406 of layer 1404 is substantially planar. Insulating material 1402 may be an electrically insulating material, such as a polymer, a dielectric material such as a photo-imagable dielectric, and/or other electrically non-conductive material.

As shown in FIG. 14, insulating material 1402 covers dies 602a and 602b.

Furthermore, as shown in FIG. 14, insulating material 1402 fills spaces 1408a and 1408b in opening 1002a adjacent to die 602a on substrate 702, and fills spaces 1410a and 1410b in opening 1002b adjacent to die 602b on substrate 702. Insulating material 1402 may fill spaces on any number of sides (edges of dies 602 perpendicular to their active surfaces) of dies 602, including all four sides, in embodiments. Spaces 1408 and 1410 may have any width. In some embodiments, an opening 1002 may have a size approximately the same as a die 602 residing therein, and thus spaces 1408 and 1410 may be very narrow or non-existent on one or more sides of die 602. Note that in an embodiment, because dies 602 are located in respective openings 1002 of thick film material 902, dies 602 are held relatively stationary during application of insulating material 1402 (as compared to applying insulating material 1402 over dies 602 when thick film material 902 is not present).

In step 116, at least one redistribution interconnect is formed on the insulating material for each die to have a first portion coupled to a terminal of a respective die and a second portion that extends away from the first portion over a portion of the insulating material. For example, FIG. 17 shows redistribution interconnects 1702a-1702c, also known as “redistribution layers (RDLs),” formed on insulating material 1402 for each of dies 602a and 602b. With reference to redistribution interconnect 1702a, for example, redistribution interconnect 1702a has a first portion 1704 and a second portion 1706.

First portion 1704 is coupled to a terminal of die 602a. Second portion 1706 extends away from first portion 1704 (e.g., laterally) over insulating material 1402, over a portion of space 1708a adjacent to die 602a. For example, second portion 1706 may extend over space 1408a (shown in FIG. 14) adjacent to die 602a in opening 1002a, and may further extend over thick film material 902. Note that not all redistribution interconnects 1702 necessarily extend over a space adjacent to a die 602. For example, redistribution interconnects 1702b and 1702c coupled to terminals of die 602a do not extend over a space adjacent to die 602a.

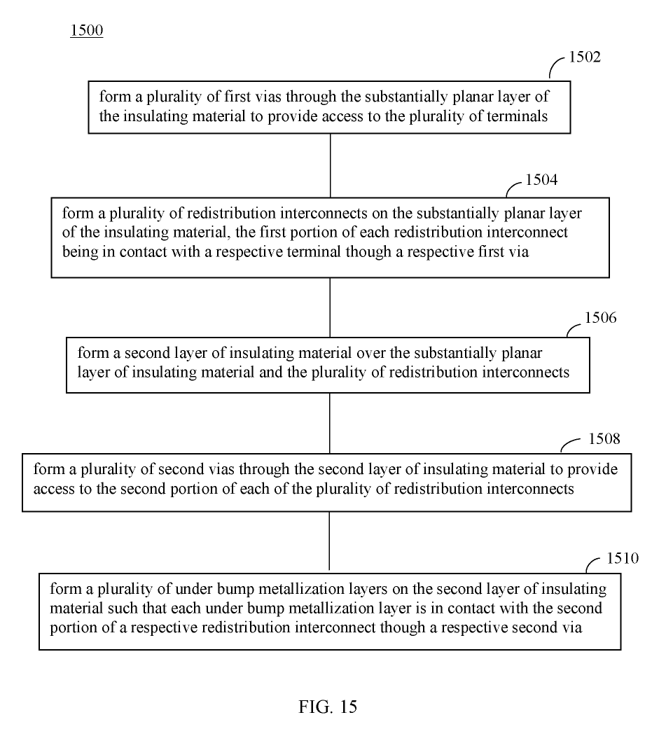

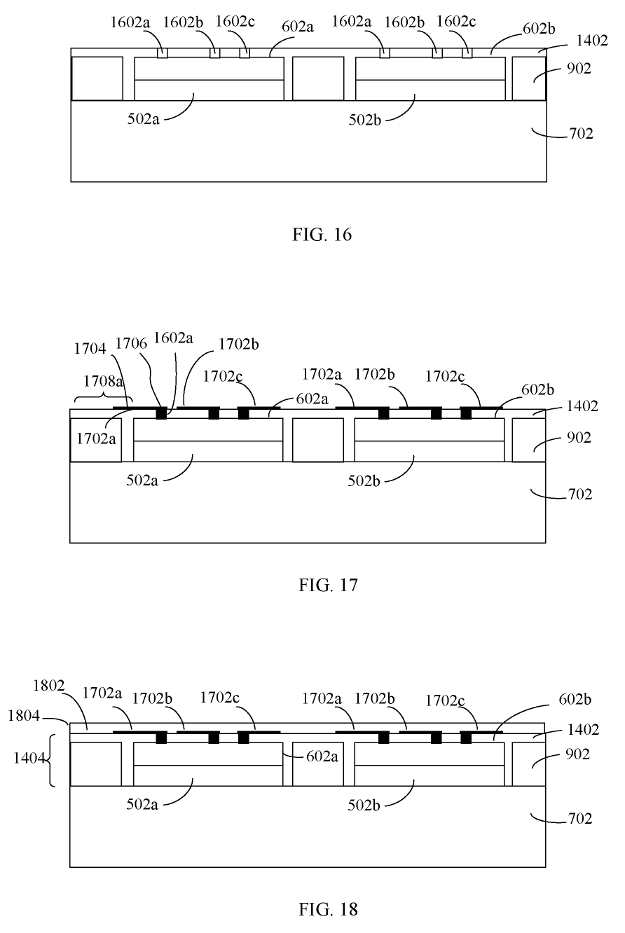

Redistribution interconnects 1702 may be formed in step 116 in any manner, including being formed according to processes used in standard wafer-level packaging fabrication processes. For instance, FIG. 15 shows a flowchart 1500 providing example steps for forming redistribution interconnects 1702, according to an embodiment of the present invention. Not all steps of flowchart 1500 need to be performed in all embodiments, and that redistribution interconnects 1702 may be formed according to processes other than flowchart 1500. Flowchart 1500 is described below with respect to FIGS. 16-20, for illustrative purposes.

Flowchart 1500 begins with step 1502. In step 1502, a plurality of first vias is formed through the substantially planar layer of the insulating material to provide access to the plurality of terminals. For example, FIG. 16 shows a cross-sectional view of substrate 702, with dies 602a and 602b covered on substrate 702 with insulating material 1402. As further shown in FIG. 16, a plurality of vias 1602a-1602c are formed through insulating material 1402 for both of dies 602a and 602b. Each via 1602 provides access to a respective terminal (e.g., one of terminals 302 shown in FIG. 3). Any number of vias 1602 may be present, depending on a number of terminals present. Note that vias 1602 may have straight vertical walls (e.g., vias 1602 may have a cylindrical shape) as shown in FIG. 16, may have sloped walls, or may have other shapes. Vias 1602 may be formed in any manner, including by etching, drilling, etc., as would be known to persons skilled in the relevant art(s).

In step 1504, a plurality of redistribution interconnects is formed on the substantially planar layer of the insulating material, the first portion of each redistribution interconnect being in contact with a respective terminal though a respective first via. For example, as shown in FIG. 17, and as described above, routing interconnects 1702a-1702c are formed on insulating material 1402 for each of dies 602a and 602b. As described above, routing interconnect 1702a has a first portion 1706 and a second portion 1704. First portion 1706 of routing interconnect 1702a is in contact with a terminal of die 602a through via 1602a (formed in step 1502), and second portion 1706 of routing interconnect 1702a extends (e.g., laterally) over insulating material 1402. In this manner, a plurality of redistribution layers 1702 are formed for dies 602a and 602b, where at least some of which extend over the space adjacent to dies 602.

Note that second portions 1702 of routing interconnects 1702 can have various shapes. For example, second portions 1702 may be rectangular shaped, may have a rounded shape, or may have other shapes. In an embodiment, first portion 1706 of routing interconnects 1702 may be similar to a standard via plating, and second portion 1704 may extend from first portion 1706 in a similar fashion as a standard metal trace formed on a substrate. Routing interconnects 1702 may be formed of any suitable electrically conductive material, including a metal such as a solder or solder alloy, copper, aluminum, gold, silver, nickel, tin, titanium, a combination of metals/alloy, etc. Routing interconnects 1702 may be formed in any manner, including sputtering, plating, lithographic processes, etc., as would be known to persons skilled in the relevant art(s).

In step 1506, a second layer of insulating material is formed over the substantially planar layer of insulating material and the plurality of redistribution interconnects. For instance, FIG. 18 shows a cross-sectional view of a second layer 1804 of an insulating material 1802 formed over first layer 1404 of insulating material 1402 and redistribution interconnects 1702. Second insulating material 1802 may be applied in any manner, conventional or otherwise, as would be known to persons skilled in the relevant art(s). For example, insulating material 1802 may be applied according to a spin on or dry film process, similar to a corresponding wafer-level process. Insulating material 1802 is applied such that layer 1804 electrically insulates a top surface of redistribution interconnects 1702. Layer 1804 may be formed or processed (e.g., polished) to be substantially planar. Insulating material 1802 may be the same material or a different material from insulating material 1402. For example, insulating material 1802 may be an electrically insulating material, such as a polymer, a dielectric material such as a photo-imagable dielectric, and/or other electrically non-conductive material.

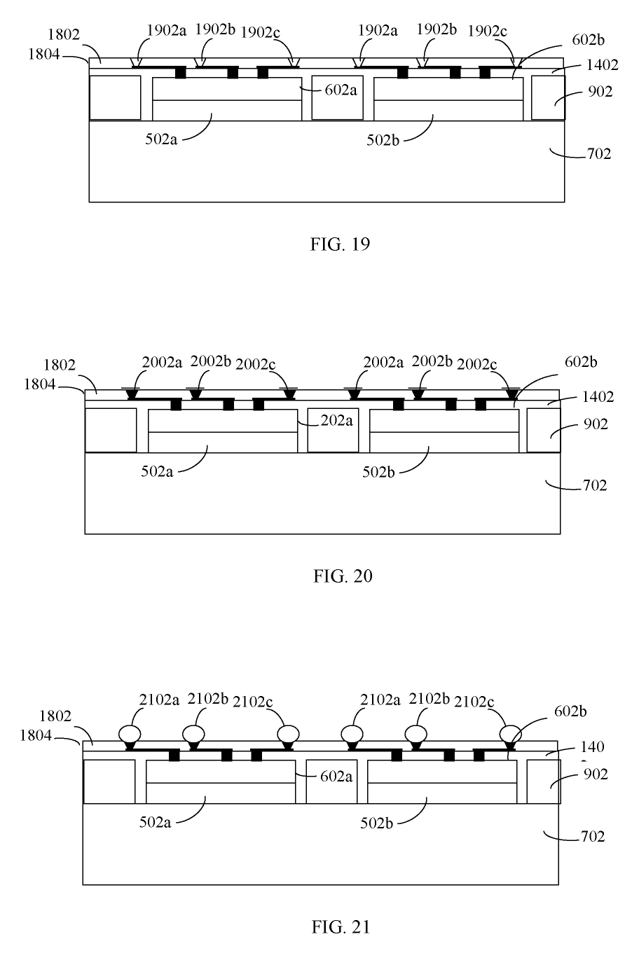

In step 1508, a plurality of second vias is formed through the second layer of insulating material to provide access to the second portion of each of the plurality of redistribution interconnects. For example, FIG. 19 shows a cross-sectional view of second vias 1902a-1902c formed through second insulating material 1802 for each of dies 602a and 602b to provide access to second portions 1704 of redistribution interconnects 1702a-1702c, respectively. Each second via 1902 provides access to a respective redistribution interconnect 1702. Any number of second vias 1902 may be present, depending on a number of redistribution interconnects present. Note that second vias 1902 may have sloped walls as shown in FIG. 19, may have straight vertical walls (e.g., vias 1902 may have a cylindrical shape), or may have other shapes. Second vias 1902 may be formed in any manner, including by etching, drilling, etc., as would be known to persons skilled in the relevant art(s).

In step 1510, a plurality of under bump metallization layers is formed on the second layer of insulating material such that each under bump metallization layer is in contact with the second portion of a respective redistribution interconnect though a respective second via. For example, FIG. 20 shows a cross-sectional view of under bump metallization layers 2002a-2002c formed in contact with second portions 1704 of respective redistribution interconnects 1702 through respective second vias 1902. Under bump metallization (UBM) layers 2002 are typically one or more metal layers formed (e.g., by metal deposition—plating, sputtering, etc.) to provide a robust interface between redistribution interconnects 1702 and a package interconnect mechanism (such as a ball interconnect). A UBM layer serves as a solderable layer for a solder package interconnect mechanism. Furthermore, a UBM provides protection for underlying metal or circuitry from chemical/thermal/electrical interactions between the various metals/alloys used for the package interconnect mechanism. In an embodiment, UBM layers 2002 are formed similarly to standard via plating.

Note that steps of flowchart 1500 may be repeated any number of times, to create further layers of redistribution interconnects. For example, FIG. 18 shows layer 1804 formed over a first layer of redistribution interconnects 1702. Steps 1504 and 1506 may be repeated, to form a second layer of redistribution interconnects 1702 on first layer 1804 in FIG. 18, and to form a next layer of insulating material 1802, similar to layer 1804, on the second layer of redistribution interconnects 1702. Steps 1504 and 1506 may be repeated any number of times, to form a stack of alternating layers of redistribution interconnects 1702 and insulating material 1802 of any suitable height. After steps 1504 and 1506 are repeated as desired, step 1508 may be performed to form second vias 1902 through the multiple layers of insulating material 1802 to provide access to second portions 1704 of the redistribution interconnects 1702 of each formed layer of redistribution interconnects 1702. Step 1510 may be performed to form under bump metallization layers 2002 in second vias 1902 that are in contact with redistribution interconnects 1702 at each formed layer of redistribution interconnects 1702.

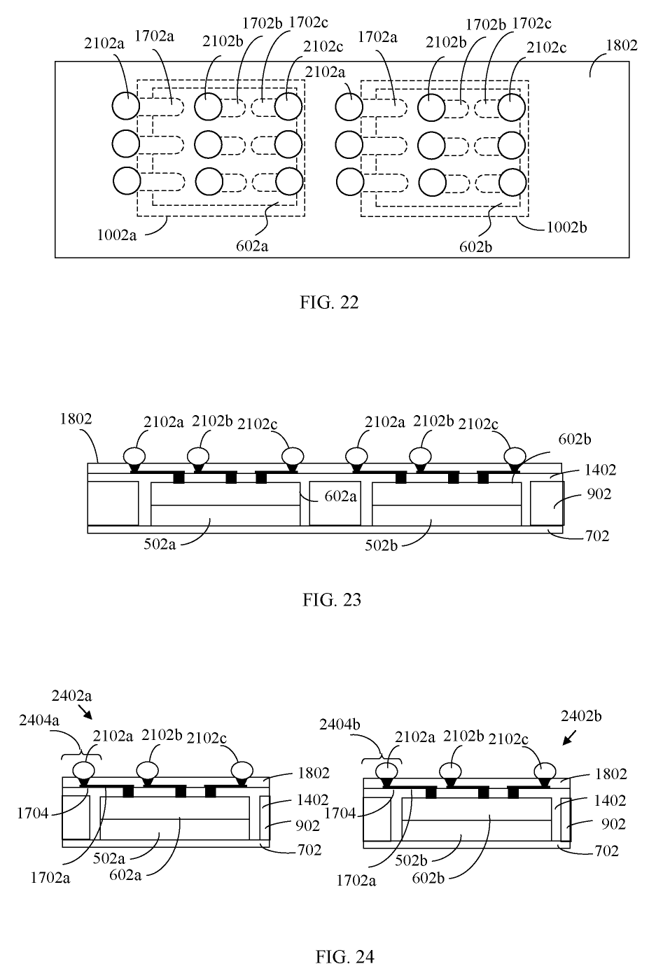

Referring back to flowchart 100, in step 118, a ball interconnect is coupled to each second portion. For example, FIG. 21 shows a cross-sectional view of ball interconnects 2102a-2102c formed on respective UBM layers 2002a-2002c for each of dies 602a and 602b. In this manner, a plurality of ball interconnects 2102 may be formed in electrical contact with respective routing interconnects 1702. For instance, FIG. 22 shows a view of a surface of insulating material 1802, where ball interconnects 2102 related to dies 602a and 602b (indicated by dotted lines) are visible, according to an example embodiment of the present invention. As shown in FIG. 22, each ball interconnect 2102 is coupled to a respective redistribution interconnect 1702 (shown as dotted lines).

Furthermore, some ball interconnects 2102 are coupled to redistribution interconnects 1702 in a manner such that the ball interconnect 2102 is over insulating material 1802 outside of a periphery of the respective die 602, instead of in an area within the die periphery. In this manner, an effective area of dies 602 is increased for attachment of ball interconnects 2102. For example, in FIG. 22, ball interconnect 2102c slightly overlaps insulating material 1402 (not indicated in FIG. 22) in cavity 1002a outside of the periphery of die 602a. Ball interconnect 2102a overlaps thick film material 902 (not indicated in FIG. 22) outside of a periphery of cavity 1002a.

In FIG. 22, ball interconnects 2102a-2102c are formed as part of a 3 by 3 array of ball interconnects 2102 for each of dies 602a and 602b. Arrays of ball interconnects 2102 of any size may be present relating to a particular die 602, depending on a number of redistribution interconnects 1702 that are present. Ball interconnects 2102 may be formed of any suitable electrically conductive material, including a metal such as a solder or solder alloy, copper, aluminum, gold, silver, nickel, tin, titanium, a combination of metals/alloy, etc. Ball interconnects 2102 may have any size and pitch, as desired for a particular application. Ball interconnects 2102 may be any type of ball interconnect, including a solder ball, a solder bump, etc. Ball interconnects 2102 may be formed in any manner, including sputtering, plating, lithographic processes, etc., as would be known to persons skilled in the relevant art(s). Ball interconnects 2102 are used to interface resulting wafer-level packages with an external device, such as a PCB.

In step 120, the substrate is thinned by backgrinding the substrate. Step 120 is optional. A backgrinding process may be performed on substrate 702 to reduce a thickness of substrate 702 to a desired amount, if desired and/or necessary. Substrate 702 may be thinned in any manner, as would be known to persons skilled in the relevant art(s). FIG. 23 shows a cross-sectional view of substrate 702 after having been thinned according to step 120. According to step 120, substrate 702 is made as thin as possible to aid in minimizing a thickness of resulting packages that are formed according to flowchart 100. For example, in an embodiment, a thinning process may be performed that completely removes substrate 702 from dies 602, and may optionally also remove some or all of adhesive material 502, from dies 602, and some of thick film material 902.

In step 122, the dies are singulated into a plurality of integrated circuit packages that each include a die and the portion of the space adjacent to the included die. Dies 602 may be singulated/diced in any appropriate manner to physically separate the dies from each other, as would be known to persons skilled in the relevant art(s). Singulation according to step 122 may result in 10s, 100s, 1000s, or even larger numbers of integrated circuit module 1802, depending on a number of dies 602 that are present.

For example, in FIG. 23, dies 602 may be singulated by cutting through first and second insulating material layers 1402 and 1802, thick film material 902, and substrate 702 (when present), to separate dies 602 from each other, with each die 602 including a portion of its adjacent space. Dies 602 may be singulated by a saw, router, laser, etc., in a conventional or other fashion. FIG. 24 shows a cross-sectional view of integrated circuit packages 2402a and 2402b, having been singulated from each other. Integrated circuit packages 2402a and 2402b respectively include dies 602a and 602b, and respective portions 2404a and 2404b of adjacent space that are filled with insulating material 1402, and which may further include thick film material 902. Second portions 1704 of redistribution interconnects 1702a extend over portions 2404a and 2404b of the adjacent space included with singulated dies 602a and 602b, respectively.

Note that in an embodiment, dies 602 may be singulated into integrated circuit packages such that multiple die 602 are included in an integrated circuit package. For example, referring to FIG. 23, an integrated circuit package may be formed by cutting through first and second insulating material layers 1402 and 1802, thick film material 902, and substrate 702 (when present), to separate dies 602a and 602b as a unit from other dies 602, to form a package that includes dies 602a and 602b. Any number of dies 602 may be included in a package.

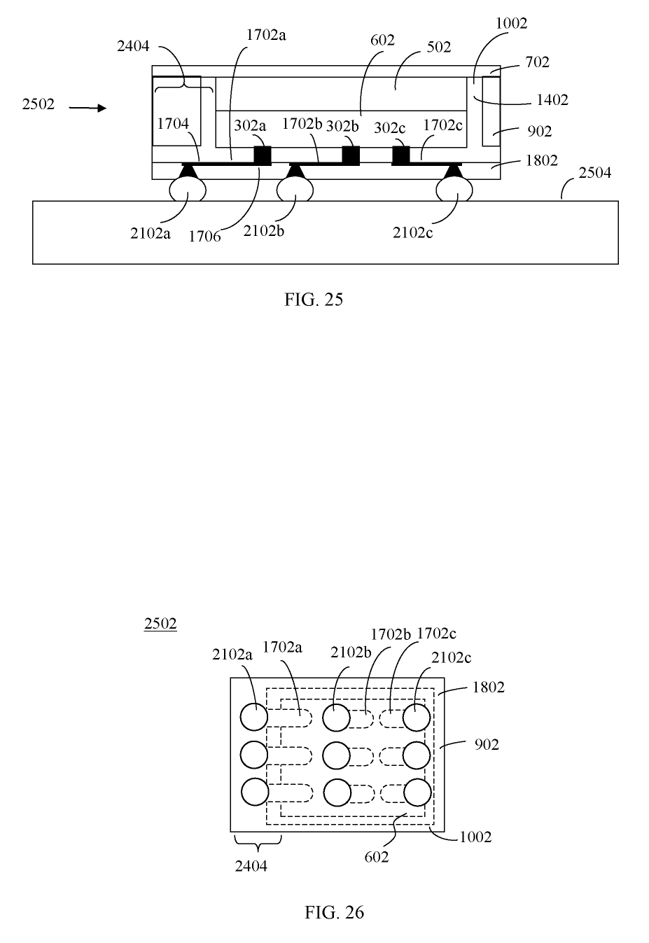

FIG. 25 shows an integrated circuit package 2502 mounted to a circuit board 2504. Integrated circuit package 2502 of FIG. 25 is an example wafer-level package, formed according to an embodiment of the present invention. Package 2502 may be formed in the manner that packages 2402a and 2402b of FIG. 24 are formed (e.g., according to flowchart 100 shown in FIG. 1). Alternatively, package 2502 may be formed by other fabrication process, including by forming package 2502 in parallel with the forming of other packages (similarly to flowchart 100) or by forming package 2502 individually. As shown in FIG. 25, package 2502 includes die 602, which has a plurality of terminals 302a-302c on a first surface, insulating material 1402, thick film material 902, redistribution interconnects 1702a-1702c, and ball interconnects 2102a-2102c. Insulating material 1402 covers the active surface of die 602, and fills space 2404 adjacent one or more sides of die 602 in opening 1002 formed by thick film material 902. Thick film material 902 may form a partial or complete ring around die 602. Redistribution interconnect 1702a on insulating material 1402 has first portion 1706 coupled to terminal 302a of die 602 through insulating material 1402, and has second portion 1704 that extends away from first portion 1706 over insulating material 1402 and thick film material 902. Ball interconnect 2102a is coupled to second portion 1704 of redistribution interconnect 1702a over space 2404. Thus, redistribution interconnect 1702 effectively expands an area of die 602 for attachment of ball interconnects.

Note that in an embodiment, the thinned portion of substrate 702 shown in FIG. 25 may be present in package 2502. Alternatively, substrate 702 may not be present in package 2502. Furthermore, in embodiments, one or more vias (e.g., first vias 1602 of FIG. 16, second vias 1902 of FIG. 19), under bump metallization layers (e.g., under bump metallization layers 2002), additional insulating material layers (e.g., second layer 1804 of insulating material 1802), and/or other additional features may be present in package 2502 to fabricate/configure redistribution interconnects 1702, as needed.

FIG. 26 show a bottom view of package 2502, where ball interconnects 2102a-2102c form a portion of a 3 by 3 array of ball interconnects 2102. Ball interconnects 2102 are used to attach package 2502 to circuit board 2504 in FIG. 25. As shown in FIG. 26, three ball interconnects 2102, including ball interconnect 2102a, are coupled through redistribution interconnects 1702, such as redistribution interconnect 1702a, to terminals of die 602. Furthermore, the three ball interconnects 2102 are over space 2404 adjacent to die 602. Thus, the area of die 602 is effectively increased by an area of space 2404 for attachment of three additional ball interconnects 2102. Embodiments of the present invention enable the attachment of any number of ball interconnects 2102, depending on the particular implementation, as would be known to persons skilled in the relevant art(s) from the teachings herein.

### Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents

What is claimed is:

1. A method for forming integrated circuit (IC) packages, comprising:
singulating a wafer into a plurality of integrated circuit dies that each include an integrated circuit region, each integrated circuit region having a plurality of terminals;
attaching a non-active surface of each of the plurality of dies to a first surface of a substrate in a corresponding opening;
forming a substantially planar layer of an insulating material over the first surface of the substrate to cover the dies in the openings on the substrate;
forming at least one redistribution interconnect on the insulating material for each die of the plurality of dies to have a first portion coupled to a terminal of a respective die and a second portion that extends away from the first portion over a portion of the insulating material adjacent to the respective die;
coupling a ball interconnect to each second portion; and
singulating the dies into a plurality of integrated circuit packages that each include a die of the plurality of dies and the portion of the insulating material adjacent to the included die.

2. The method of claim 1, further comprising:
forming a substantially planar layer of a thick film material on the first surface of the substrate; and
forming a plurality of openings in the layer of the thick film material; and
wherein said attaching comprises:
attaching a non-active surface of each of the plurality of dies to a first surface of a substrate in a corresponding opening of the plurality of openings.

3. The method of claim 2, wherein said forming a substantially planar layer of an insulating material over the first surface of the substrate to cover the dies in the openings on the substrate comprises:
forming the substantially planar layer of an insulating material on the layer of the thick film material.

4. The method of claim 3, wherein said singulating comprises:
singulating the dies into a plurality of integrated circuit packages that each include a die of the plurality of dies, the portion of the insulating material adjacent to the included die, and a portion of the thick film material adjacent to the included die.

5. The method of claim 1, wherein the substrate is a second wafer formed of a same material as the first wafer, wherein said attaching comprises:
attaching the non-active surface of each of the plurality of dies to the second wafer.

6. The method of claim 1, further comprising:
backgrinding the received wafer.

7. The method of claim 1, wherein said forming the at least one redistribution interconnect on the insulating material comprises:
forming a plurality of first vias through the substantially planar layer of the insulating material to provide access to the plurality of terminals;
forming a plurality of redistribution interconnects on the substantially planar layer of the insulating material, the first portion of each redistribution interconnect being in contact with a respective terminal though a respective first via;
forming a second layer of insulating material over the substantially planar layer of insulating material and the plurality of redistribution interconnects;
forming a plurality of second vias through the second layer of insulating material to provide access to the second portion of each of the plurality of redistribution interconnects; and
forming a plurality of under bump metallization layers on the second layer of insulating material such that each under bump metallization layer is in contact with the second portion of a respective redistribution interconnect though a respective second via.

8. The method of claim 5, wherein said coupling a ball interconnect to each second portion comprises:
forming a ball interconnect on each under bump metallization layer.

9. An integrated circuit (IC) package, comprising:
a substantially planar thick film material that forms a opening;
an integrated circuit die positioned in the opening that has a plurality of terminals on a first surface of the integrated circuit die;
a first layer of an insulating material that covers the first surface of the die and a surface of the thick film material, and fills a space adjacent to the die in the opening;
a redistribution interconnect on the first layer of the insulating material that has a first portion coupled to a terminal of the die through the first layer and a second portion that extends away from the first portion over the insulating material that fills the space adjacent to the die in the opening; and
a ball interconnect coupled to the second portion of the redistribution interconnect.

10. The package of claim 9, further comprising:
a plurality of first vias through the first layer of the insulating material to provide access to the plurality of terminals;
wherein the first portion of the redistribution interconnect is coupled to the terminal of the die through a first via.

11. The package of claim 10, further comprising:
a second layer of insulating material over the first layer of insulating material and the redistribution interconnect; and
a second via through the second layer of insulating material to provide access to the second portion of the redistribution interconnect;
wherein the ball interconnect is coupled to the second portion of the redistribution interconnect through the second via.

12. The package of claim 11, further comprising:
an under bump metallization layer on the second layer of insulating material in contact with the second portion of the redistribution interconnect though the second via;
wherein the ball interconnect is coupled to the second portion of the redistribution interconnect through the under bump metallization layer and the second via.

13. The package of claim 9, further comprising:
a substrate material;
wherein a second surface of the die is attached to the substrate material through the opening.

14. The package of claim 13, wherein the substrate material comprises a same material as the die.

15. A wafer level integrated circuit package structure, comprising:
a substrate;
a layer of a thick film material formed on the first surface of the substrate having a plurality of openings formed therein;
a plurality of integrated circuit dies that each include an integrated circuit region, wherein a non-active surface of each die of the plurality of dies is attached to a first surface of the substrate in a corresponding opening;
an insulating material that covers the dies in the openings on the substrate;
a plurality of redistribution interconnects on the insulating material, wherein the plurality of redistribution interconnects includes a redistribution interconnect for each die of the plurality of dies having a first portion coupled to a terminal of a respective die and a second portion that extends away from the first portion over a portion of the insulating material adjacent to the respective die; and
a ball interconnect coupled to each second portion.

16. The wafer level integrated circuit package structure of claim 15, wherein the substrate is a second wafer formed of a same material as plurality of dies.

17. The wafer level integrated circuit package structure of claim 15, further comprising:
a plurality of first vias through the substantially planar layer of the insulating material to provide access to the plurality of terminals, wherein the first portion of the redistribution interconnect for each die is in contact with the terminal of the respective die though a respective first via;
a second layer of insulating material over the substantially planar layer of insulating material and the plurality of redistribution interconnects; and
a plurality of second vias through the second layer of insulating material that provide access to the second portion of each of the plurality of redistribution interconnects;
wherein a ball interconnect is coupled to each second portion through a respective second via.

18. The wafer level integrated circuit package structure of claim 17, further comprising:
a plurality of under bump metallization layers on the second layer of insulating material such that each under bump metallization layer is in contact with the second portion of a respective redistribution interconnect though a respective second via;
wherein a ball interconnect is coupled to each second portion through the respective second via and a respective under bump metallization layer.
